(19) United States
(12) Patent Application Publication
(10) Pub. No.: US 2015/0268693 A1
(43) Pub. Date: Sep. 24, 2015

(54) DISPLAY APPARATUS

(71) Applicant: Samsung Display Co., LTD., Yongin-City (KR)

(72) Inventors: Jin-Ho OH, Seoul (KR); Dong-Ho KIM, Seoul (KR); Bong-Jun PARK, Suwon-si (KR); Yong SON, Suwon-si (KR); Yi-Seul SONG, Uiwang-si (KR); Sung-Jin CHOI, Hwaseong-si (KR); Jee-Hoon HAN, Asan-si (KR)

(21) Appl. No.: 14/487,770

(22) Filed: Sep. 16, 2014

(30) Foreign Application Priority Data
Mar. 20, 2014 (KR) 10-2014-0032938

(51) Int. Cl. G06F 1/16; H05K 5/02

(52) U.S. Cl. CPC G06F 1/1601; H05K 5/0204; H05K 5/0247; H05K 5/026

(57) ABSTRACT

A display apparatus includes a display portion configured to display an image, a frame surrounding the display portion, and a block in which a groove is defined. The frame includes a plurality of protrusions. The protrusions have same shapes and are arranged spaced apart by a uniform gap. The groove of the block is configured to receive a protrusion of the frame.

This application claims priority to Korean Patent Application No. 10-2014-0032938, filed on Mar. 20, 2014, and all the benefits accruing therefrom under 35 U.S.C. §119, the disclosure of which is incorporated by reference herein in its entirety.

### BACKGROUND

1. Field

Exemplary embodiments of the invention relate to a display apparatus.

More particularly, exemplary embodiments of the invention relate to a display apparatus capable of designing a bezel therefor.

2. Description of the Related Art

A display apparatus having a relatively light weight and small size has been manufactured. A cathode ray tube (“CRT”) display apparatus has been used due to a performance and a competitive price thereof. However the CRT display apparatus has a weakness with a size or portability thereof. Therefore a display apparatus such as a plasma display apparatus, a liquid crystal display apparatus and an organic light emitting display apparatus has been highly regarded due to a relatively small size, light weight and low-power-consumption thereof.

### SUMMARY

A display apparatus includes a display area, and a frame which surrounds the display area. The frame includes a bezel surface which is parallel with the display area. The bezel surface is visible to a user who views the display apparatus. However, a design of the bezel surface is already determined when the display apparatus is manufactured, so that the user cannot change the design of the bezel surface.

One or more exemplary embodiment of the invention provides a display apparatus capable of having a changeable design a bezel of the display apparatus after manufacturing thereof.

According to an exemplary embodiment of the invention, a display apparatus includes a display portion configured to display an image, a frame surrounding the display portion, and a block in which a groove is defined. The frame includes a plurality of protrusions. The protrusions have same shapes and are arranged spaced apart by a uniform gap. The groove of the block is configured to receive a protrusion among the plurality of protrusions of the frame.

In an exemplary embodiment, the display apparatus may further includes a first frame portion which extends in a first direction, a second frame portion which extends in the first direction and is spaced apart from the first frame portion, a third frame portion which extends in a second direction and connects the first frame portion and the second frame portion, and a fourth frame portion which extends in the second direction and connects the first frame portion and the second frame portion. The second direction may be substantially perpendicular to the first direction. The first frame portion may include a first bezel surface and a first side surface. The first bezel surface may be in a plane which is parallel with a plane defined by the first and second directions. The first side surface may be connected with the first bezel surface and extend in a third direction which is substantially perpendicular to the first and second directions. The second frame portion may include a second bezel surface and a second side surface. The second bezel surface may be in the plane which is parallel with the plane defined by the first and second directions. The second side surface may be connected with the second bezel surface and extends in the third direction. The third frame portion may include a third bezel surface and a third side surface. The third bezel surface may be in the plane which is parallel with the plane defined by the first and second directions. The third side surface may be connected with the third bezel surface and extends in the third direction. The fourth frame portion may include a fourth bezel surface and a fourth side surface. The fourth bezel surface may be in the plane which is parallel with the plane defined by the first and second directions. The fourth side surface may be connected with the fourth bezel surface and extends in the fourth direction. The protrusions may be extended from the first to fourth bezel surfaces.

In an exemplary embodiment, the protrusions may be further extended from the first side surface of the first frame portion.

In an exemplary embodiment, a plurality of grooves may be defined in the second side surface of the second frame portion. Each groove of the second side surface may be a same shape as the groove defined in the block.

In an exemplary embodiment, each of a protrusion among the plurality of protrusions may include an extending portion extended from the first, second, third or fourth bezel surface, and a head portion extended from the extending portion.

In an exemplary embodiment, the extending portion may have a cylindrical shape. The head portion may have a truncated circular cone shape.

In an exemplary embodiment, a recess may be defined in the head portion of the protrusion. The protrusion may further include a terminal disposed in the recess and configured to receive an electrical signal thereto and to output the electrical signal therefrom.

In an exemplary embodiment, the block may be a functional block including a connecting terminal disposed in the groove thereof and configured to be electrically connected to the terminal of the protrusion. The protrusion of the frame received in the groove of the functional block may electrically connect the connecting terminal of the functional block and the terminal of the protrusion.

In an exemplary embodiment, the functional block may be configured to receive the electrical signal and output sound.

In an exemplary embodiment, the functional block may be a storage medium which is configured to receive the electrical signal thereto and output the electrical signal therefrom.

In an exemplary embodiment, the first frame portion further comprises a first input/output connector which is configured to receive an electrical signal thereto and output the electrical signal therefrom.

In an exemplary embodiment, the block may be a functional block including a second input/output connector which is configured to be electrically connected to the first input/output connector of the first frame portion.

In an exemplary embodiment, the block may include a body portion, and a decorative portion disposed on the body portion. The decorative portion may include a different material from that of the body portion.

In an exemplary embodiment, the decorative portion may include lacquer, wood or metal.

In an exemplary embodiment, a plurality of grooves may be defined in a bottom surface of the block.

In an exemplary embodiment, a plurality of protrusions may be extended from a top surface of the block. The top surface may be opposite to the bottom surface. The plurality of protrusions of the block may have a shape substantially same as the plurality of protrusions of the frame.

According to an exemplary embodiment of the invention, a display apparatus includes a display portion to display an image, and a frame surrounding the display portion. A plurality of protrusions may be protruded from the frame. The frame protrusions may have same shapes as each other and be arranged spaced apart by a uniform gap, and to which are combined grooves of a block which is configured to be combined with the frame.

According to one or more exemplary embodiment of the present invention, a plurality of protrusions is disposed on a frame of a display apparatus. The protrusions have same shapes each other, and are arranged spaced apart by a uniform gap, so that a block may be combined with any portion of the frame. Thus, a user may design a bezel of the display apparatus.

In addition, one or more exemplary embodiment of the blocks may include various materials, so that the user may further design a bezel of the display apparatus.

In addition, one or more exemplary embodiment of the blocks is a functional block configured to be combined with the frame and provide various functions such as storage, audio or visual functions.

### BRIEF DESCRIPTION OF THE DRAWINGS

The above and other features of the invention will become more apparent by describing in detail exemplary embodiments thereof with reference to the accompanying drawings, in which:

FIG. 1 is a perspective view illustrating an exemplary embodiment of a display apparatus according to the invention;

FIGS. 2A and 2B are perspective views illustrating an exemplary embodiment of a block of the display apparatus of FIG. 1;

FIGS. 3A and 3B are a perspective view illustrating another exemplary embodiment of a display apparatus according to the invention;

FIG. 4 is an enlarged perspective view illustrating an exemplary embodiment of a portion of a bezel surface of a frame portion of the display apparatus of FIG. 1;

FIGS. 5A and 5B are perspective views illustrating another exemplary embodiment of a block of the display apparatus of FIG. 1 in detail;

FIG. 6 is an enlarged perspective view illustrating another exemplary embodiment of a portion of a bezel surface of a frame portion of a display apparatus according to the invention;

FIGS. 7A and 7B are perspective views illustrating still another exemplary embodiment of a block of a display apparatus according to the invention; and

FIG. 8 is a perspective view of an exemplary embodiment of a surrounding assembly for a display apparatus according to the invention.

### DETAILED DESCRIPTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, the element or layer can be directly on, connected or coupled to another element or layer or intervening elements or layers. In contrast, when an element is referred to as being “directly on,” “directly connected to” or “directly coupled to” another element or layer, there are no intervening elements or layers present. As used herein, connected may refer to elements being physically and/or electrically connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “top,” “bottom” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described with respect to a “bottom” relative to other elements or features would then be oriented with respect to a “top” relative to the other elements or features. Thus, the exemplary term “top” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the invention will be explained in detail with reference to the accompanying drawings.

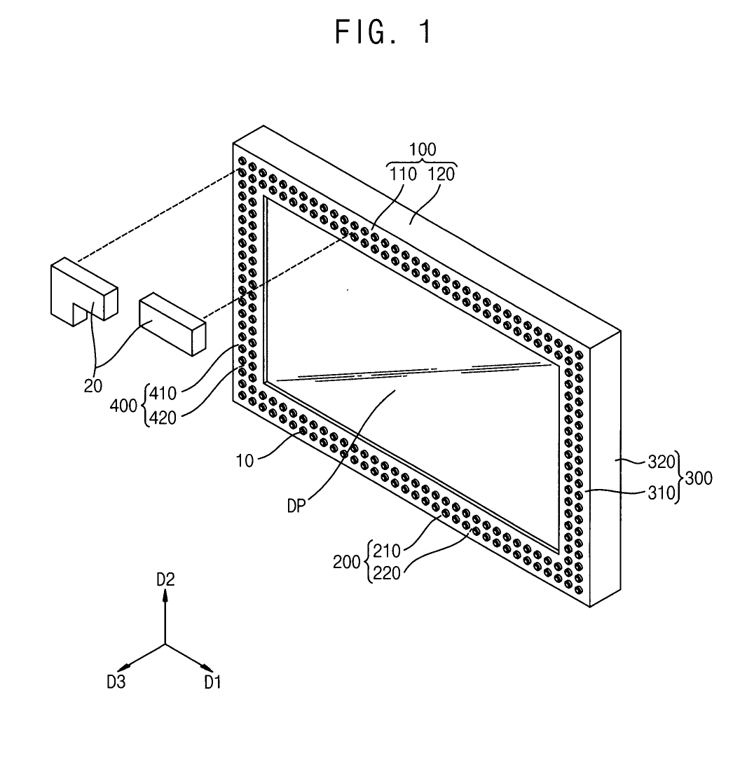

FIG. 1 is a perspective view illustrating an exemplary embodiment of a display apparatus according to the invention.

Referring to FIG. 1, a display apparatus includes a display portion DP and a frame. The frame includes a first frame portion 100, a second frame portion 200, a third frame portion 300 and a fourth frame portion 400.

The display portion DP is configured to display an image. In an exemplary embodiment, for example, the display portion DP may be a liquid crystal display panel, but the invention is not limited thereto. The display portion DP may have a rectangular shape extending in a first direction D1 and a second direction D2, in a plan view. The second direction D2 is substantially perpendicular to the first direction D1.

The frame surrounds the display portion DP. The frame exposes the display portion DP to expose the image on the display portion DP to a user. The frame collectively includes the first frame portion 100, the second frame portion 200, the third frame portion 300 and the fourth frame portion 400.

The first frame portion 100 extends in the first direction D1. The first frame portion 100 includes a first bezel surface 110 and a first side surface 120.

The first bezel surface 110 is disposed on a plane parallel with the plane defined by the first and second directions D1 and D2. The first side surface 120 is connected to the first bezel surface 110, and disposed on a plane parallel with the plane defined by the first direction D1 and a third direction D3. The third direction D3 is substantially perpendicular to the first and second directions D1 and D2.

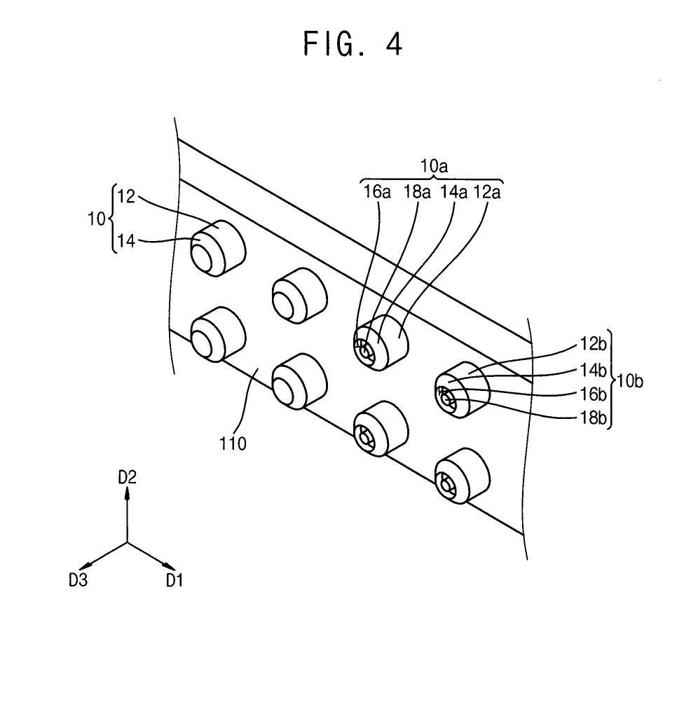

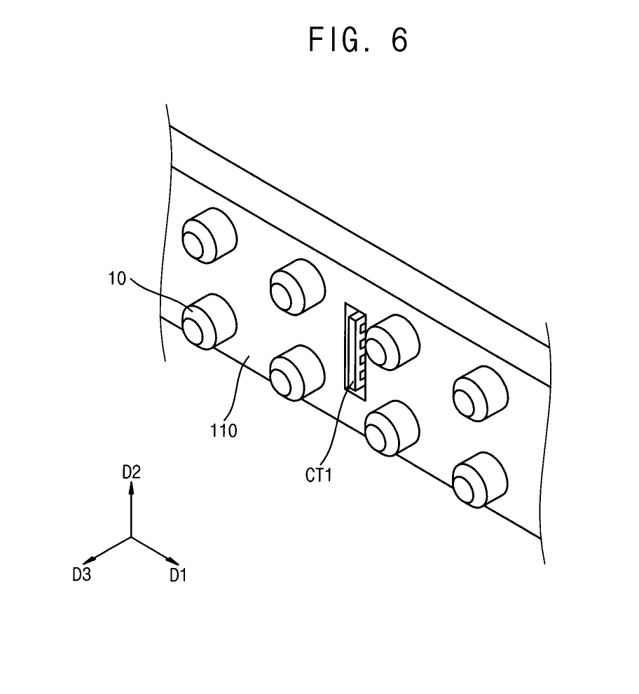

A plurality of protrusions 10 is disposed on the first bezel surface 110. The protrusions 10 may have a same shape as each other and be arranged by a predetermined gap. In an exemplary embodiment, for example, each of the protrusions 10 may have a cylindrical shape, and the plurality of protrusions 10 is disposed on the first bezel surface 110 may be arranged in the first direction D1 along the first bezel surface 110 in double columns elongated in the first direction D1. Detailed explanation about the protrusions 10 will be mentioned in FIGS. 4 and 6.

The second frame portion 200 extends in the first direction D1 and is spaced apart from the first frame portion 100. The second frame portion 200 includes a second bezel surface 210 and a second side surface 220.

The second bezel surface 210 is disposed on a plane parallel with the plane defined by first and second directions D1 and D2. The second side surface 220 is connected to the second bezel surface 210, and disposed on a plane parallel with the plane defined by the first direction D1 and the third direction D3.

A plurality of protrusions 10 is disposed on the second bezel surface 210. The protrusions 10 may have a same shape as each other and be arranged by a predetermined gap. In an exemplary embodiment, for example, each of the protrusions 10 may have a cylindrical shape, and the plurality of protrusions 10 disposed on the second bezel surface 210 may be arranged in the first direction D1 along the second bezel surface 210 in double columns elongated in the first direction D1.

The third frame portion 300 extends in the second direction D2 and connects the first frame portion 100 and the second frame portion 200 to each other. The third frame portion 300 includes a third bezel surface 310 and a third side surface 320.

The third bezel surface 310 is disposed on a plane parallel with the plane defined by the first and second directions D1 and D2. The third side surface 320 is connected to the third bezel surface 310, and disposed on a plane parallel with the plane defined by the second direction D2 and the third direction D3.

A plurality of protrusions 10 is disposed on the third bezel surface 310. The protrusions 10 may have a same shape to each other and be arranged by a predetermined gap. In an exemplary embodiment, for example, each of the protrusions 10 may have a cylindrical shape, and the plurality of protrusions 10 is disposed on the third bezel surface 310 may be arranged in the second direction D2 along the third bezel surface 310 in double columns elongated in the second direction D2.

The fourth frame portion 400 extends in the second direction D2 and connects the first frame portion 100 and the second frame portion 200 to each other. The fourth frame portion 400 is spaced apart from the third frame portion 300. The fourth frame portion 400 includes a fourth bezel surface 410 and a fourth side surface 420.

The fourth bezel surface 410 is disposed on a plane parallel with the plane defined by the first and second directions D1 and D2. The fourth side surface 420 is connected to the fourth bezel surface 410, and disposed on a plane parallel with the plane defined by the second direction D2 and the third direction D3.

A plurality of protrusions 10 is disposed on the fourth bezel surface 410. The protrusions 10 may have a same shape to each other and be arranged by a predetermined gap. In an exemplary embodiment, for example, each of the protrusions 10 may have a cylindrical shape, and the plurality of protrusions 10 is disposed on the fourth bezel surface 410 may be arranged in the second direction D2 along the fourth bezel surface 410 in double columns elongated in the second direction D2.

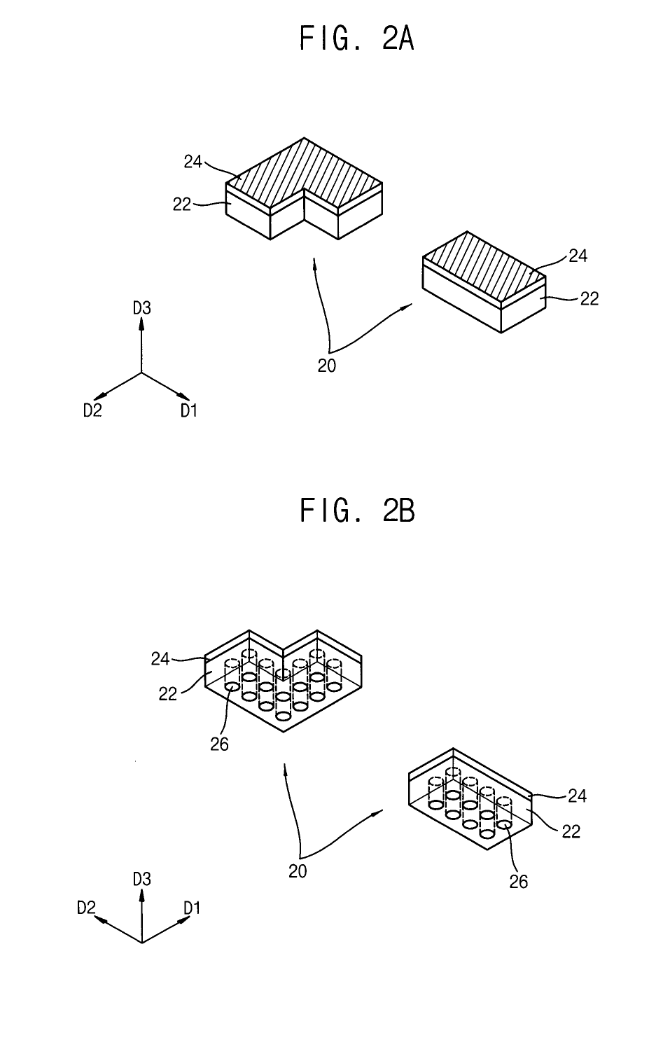

A plurality of blocks 20 may be combined with the frame. The frame 20 may have various shapes. The block 20 may have a groove defined in a bottom surface thereof to combine the block 20 with the protrusion 10 of first to fourth bezel surfaces 110 to 410 of the frame. A plurality of grooves may be defined in the bottom surface corresponding to arrangement of the protrusions 10. Detailed explanation of the blocks 20 will be mentioned in FIGS. 2A and 2B.

The protrusions 10 have same shapes and are arranged in a uniform gap, so that the blocks 20 may be combined with a single protrusion or more than one protrusion on any portion of the frame. Thus, a user may design a bezel of the display apparatus by combining various types of the blocks 20 at any position of the first to fourth bezel surface 110 to 410.

FIGS. 2A and 2B are perspective views illustrating an exemplary embodiment of blocks of the display apparatus of FIG. 1 in detail.

Referring to FIGS. 2A and 2B, each individual block 20 includes a body portion 22 and a decorative portion 24. While 20 is indicated as including more than one individual block, it is understood that an individual and discrete block may be labeled as 20.

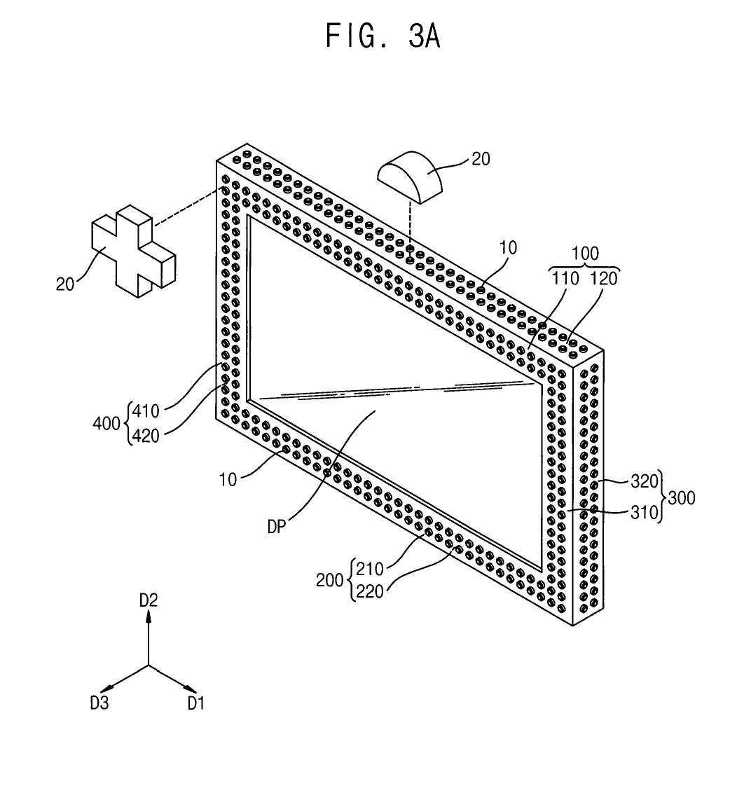

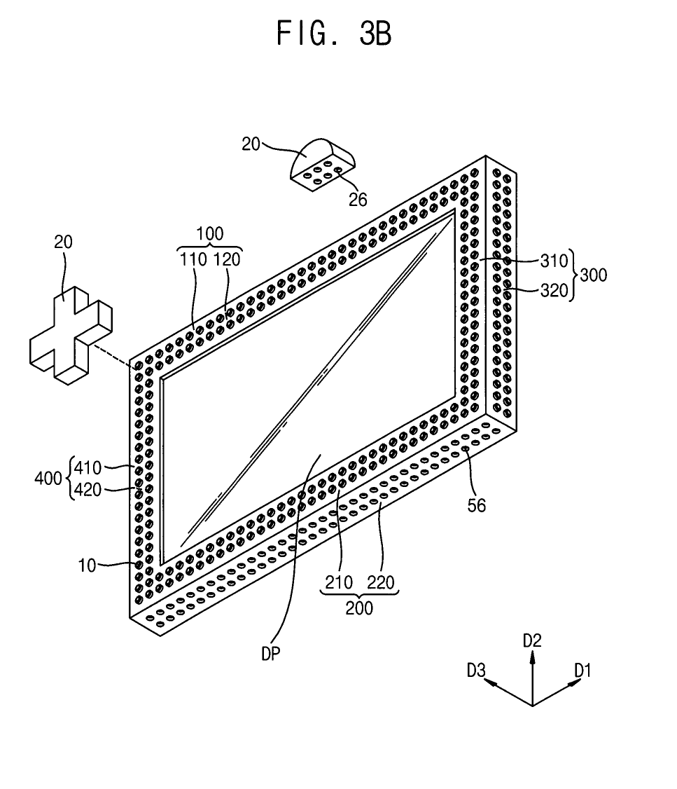

The body portion 22 may have various shapes in a plane parallel with the plane defined by first and second direction D1 and D2. The second direction D2 is substantially perpendicular to the first direction D1. In an exemplary embodiment, for example, the body portion 22 may have an L-shape (left images in FIGS. 2A and 2B) or an I-shape in the plane which is parallel with the plane defined by the first and second direction D1 and D2. The right images in FIGS. 2A and 2B may be considered as having the I-shape for convenience of explanation. Other planar shapes of the block 20 include, but are not limited to, a cross-shape (refer to FIGS. 3A and 3B), a semi-circular shape (refer to FIGS. 3A and 3B), etc.

The decorative portion 24 is disposed on the body portion 22 in a cross-sectional direction. The decorative portion 24 may include various materials to design a bezel portion of a display apparatus. In an exemplary embodiment, for example, the decorative portion 24 may include materials such as lacquer or lacquer-like, wood or wood-like, metal or metal-like, etc. The decorative portion 24 of the block 20, which is combined with a first to fourth bezel surface of the frame of the display apparatus, is visible to a user when the user observes the display apparatus (refer to the above explanation with reference to FIG. 1).

Although the decorative portion 24 is shown disposed on a top surface of the body portion 22 in the illustrated exemplary embodiment, the decorative portion 24 may also be disposed on a side surface of the body portion 22.

A groove 26 is defined recessed from a bottom surface of the body portion 22 and configured to receive a protrusion of the frame (refer to 10 of FIG. 1). A plurality of grooves 26 may be defined recessed from the bottom surface of a single discrete block 20 and corresponding to the arrangement of the protrusions 10 of the frame, such as by a uniform gap. The grooves 26 receive the protrusions 10 of the frame, so that the block 20 may be combined with the frame of the display apparatus.

Although an individual one of the block 20 includes the body portion 22 and the decorative portion 24 in the illustrated exemplary embodiment, the block 20 may have various shapes and configurations. In an exemplary embodiment, for example, an entire of the block 20 may include a specific material. The entire of the block 20 may include a single layer structure, such as including the specific material, where the block of the illustrated exemplary embodiment includes a multilayer structure.

In addition, an individual one of the block 20 may have various three-dimensional structures. In an exemplary embodiment, for example, the block 20 may have a specific shape to combine with the protrusion 10 of the frame. In addition, multiple layers of the blocks 20 may be combined with each other on bezel surface of the frame. In an exemplary embodiment, for example, a plurality of protrusions are disposed extended from an upper surface of the block 20 so that grooves 26 of another block 20 may be combined with the protrusion of the block 20. The block protrusion may have a shape substantially same as the protrusion 10 of the frame, but the invention is not limited thereto. In an exemplary embodiment, the block 20 protrusions disposed extended from an upper surface of the block 20 may be configured to engage with other available block configurations, such as those provided by LEGO™ brand blocks.

Thus, a user may design a bezel of the display apparatus by combining various types of the blocks on the any position of the frame of the display apparatus.

FIGS. 3A and 3B are a perspective view illustrating another exemplary embodiment of a display apparatus according to the invention.

Referring to FIGS. 3A and 3B, a display apparatus is substantially same as a display apparatus of FIG. 1, except for first to fourth sides 120, 220, 320 and 420. Thus, any further detailed descriptions concerning the same elements will be briefly described or will be omitted.

The display apparatus includes a display portion DP and a frame. The frame includes a first frame portion 100, a second frame portion 200, a third frame portion 300 and a fourth frame portion 400.

The first frame portion 100 includes a first bezel surface 110 and a first side surface 120. The second frame portion 200 includes a second bezel surface 210 and a second side surface 220. The third frame portion 300 includes a third bezel surface 310 and a third side surface 320. The fourth frame portion 400 includes a fourth bezel surface 410 and a fourth side surface 420.

A plurality of protrusions 10 is disposed on the first bezel surface 110. The protrusions 10 may have a same shape as each other and be arranged by a predetermined gap. A plurality of protrusions 10 is disposed on the second bezel surface 210. The protrusions 10 may have a same shape as each other and be arranged by a predetermined gap. A plurality of protrusions 10 is disposed on the third bezel surface 310. The protrusions 10 may have a same shape as each other and be arranged by a predetermined gap. A plurality of protrusions 10 is disposed on the fourth bezel surface 410. The protrusions 10 may have a same shape as each other and be arranged by a predetermined gap.

A plurality of protrusions 10 is additionally disposed on the first side surface 120 of the first frame portion 100. The protrusions 10 may have a same shape as each other and be arranged by a predetermined gap. In an exemplary embodiment, for example, each of the protrusions 10 disposed on the first side surface 120 of the first frame portion 100 has a cylindrical shape, and the plurality of protrusions 10 disposed on the first side surface 120 may be arranged in a first direction D1 along the first side surface 120 in double columns elongated in the first direction D1.

A plurality of grooves 56 is defined recessed in the second side surface 220 of the second frame portion 200. The grooves 56 may have a same shape as each other and be arranged by a predetermined gap. In an exemplary embodiment, for example, each of the grooves 56 defined recessed in the second side surface 220 of the second frame portion 200 has a cylindrical shape, and the plurality of grooves 56 defined recessed in the second side surface 220 may be arranged in the first direction D1 along the second side surface 220 in double columns elongated in the first direction D1.

A plurality of protrusions 10 is additionally disposed on the third side surface 320 of the third frame portion 300. The protrusions 10 may have a same shape as each other and be arranged by a predetermined gap. In an exemplary embodiment, for example, each of the protrusions 10 has a cylindrical shape, and the plurality of protrusions 10 disposed on the third side surface 320 may be arranged in a second direction D2 along the third side surface 320 in double columns elongated in the second direction D2.

A plurality of protrusions 10 is additionally disposed on the fourth side surface 420 of the fourth frame portion 400. The protrusions 10 may have a same shape as each other and be arranged by a predetermined gap. In an exemplary embodiment, for example, each of the protrusions 10 has a cylindrical shape, and the plurality of protrusions 10 disposed on the fourth side surface 420 may be arranged in the second direction D2 along the fourth side surface 420 in double columns elongated in the second direction D2.

A plurality of individual discrete blocks 20 may be combined with the frame. An individual discrete block 20 may have various shapes. The block 20 may have a groove 26 defined in a bottom surface thereof and configured such that the block is combinable with the protrusion 10 of the frame. The grooves 26 may be recessed in the bottom surface of the block 20 and correspond to an arrangement of the protrusions 10 of the frame.

Accordingly, one or more exemplary embodiment of the block 20 may be combined with the first, second and fourth side surfaces 120, 220 and 420 as well as with the first, second and fourth bezel surfaces 110, 120 and 410 of the frame. Although not shown in figures, a protrusion, which has a shape substantially same as the protrusion 10 of the frame, may be disposed on the block 20 and configured to be received in the groove 56 of the second side surface 220 of the second frame portion 200, so that the block 20 may be combined with the second side surface 220.

FIG. 4 is an enlarged perspective view illustrating an exemplary embodiment of a portion of a bezel surface of a frame portion of the display apparatus of FIG. 1. While the first bezel surface 110 of first frame portion 100 is illustrated in FIG. 4, the features of the exemplary embodiment are applicable to the second to the fourth frame portions 200 to 400.

Referring to FIG. 4, a plurality of protrusions 10 are disposed on a first bezel surface 110 of a first frame portion 100. A first connecting protrusion 10a and a second connecting protrusion 10b are further disposed on the first bezel surface 110 including the protrusions 10.

Each of the protrusions 10 includes an extending portion 12 and a head portion 14. The extending portion 12 extends in the third direction D3 from the first bezel surface 110. The extending portion 12 may have a cylindrical shape. The head portion 14 extends in the third direction D3 from the extending portion 12. The head portion 14 may have a smaller width at a distal end thereof than at a location nearer to the extending portion 12. Thus, the head portion 14 may have a truncated circular cone shape. The head portion 14 may form a substantially solid outer distal end surface of the protrusion 10.

The first connecting protrusion 10a includes a first extending portion 12a, a first head portion 14a, a first recess 16a and a first terminal 18a. The first extending portion 12a extends in the third direction D3 from the first bezel surface 110. The first extending portion 12a may have a cylindrical shape. The first head portion 14a extends in the third direction D3 from the first extending portion 12a. The first head portion 14a may have a smaller width at a distal end thereof than at a location nearer to the first extending portion 12a. Thus, the first head portion 14a may have a truncated circular cone shape.

The first recess 16a may be defined in the first head portion 14a. The first terminal 18a is disposed in the first recess 16a. An electrical signal may be outputted from the first terminal 18a. In an exemplary embodiment, for example, a power signal may be outputted through the first terminal 18a. A power voltage and a ground voltage may be applied to each of first terminals 18a of two first connecting protrusions 10a adjacent to each other.

The second connecting protrusion 10b includes a second extending portion 12b, a second head portion 14b, a second recess 16b and a second terminal 18b. The second extending portion 12b extends in the third direction D3 from the first bezel surface 110. The second extending portion 12b may have a cylindrical shape. The second head portion 14b extends in the third direction D3 from the second extending portion 12b. The second head portion 14b may have a smaller width at a distal end thereof than at a location nearer to the second extending portion 12b. Thus, the second head portion 14b may have a truncated circular cone shape.

The second recess 16b is defined in the second head portion 14b. The second terminal 18b is disposed in the second recess 16b. An electrical signal may be outputted from the second terminal 18b. In an exemplary embodiment, for example, a first signal may be outputted through the second terminal 18b. A first signal and a second signal may be applied to each of second terminals 18b of two second connecting protrusions 10b adjacent to each other.

The protrusion 10, the first connecting protrusion 10a and the second connecting protrusion 10b may have a same shape as each other and may be arranged spaced apart from each other at a predetermined gap, so that a groove of a block (refer to 26 of FIGS. 2A and 2B) may receive any one of the protrusion 10, the first connecting protrusion 10a and the second connecting protrusion 10b according to a design of the display apparatus.

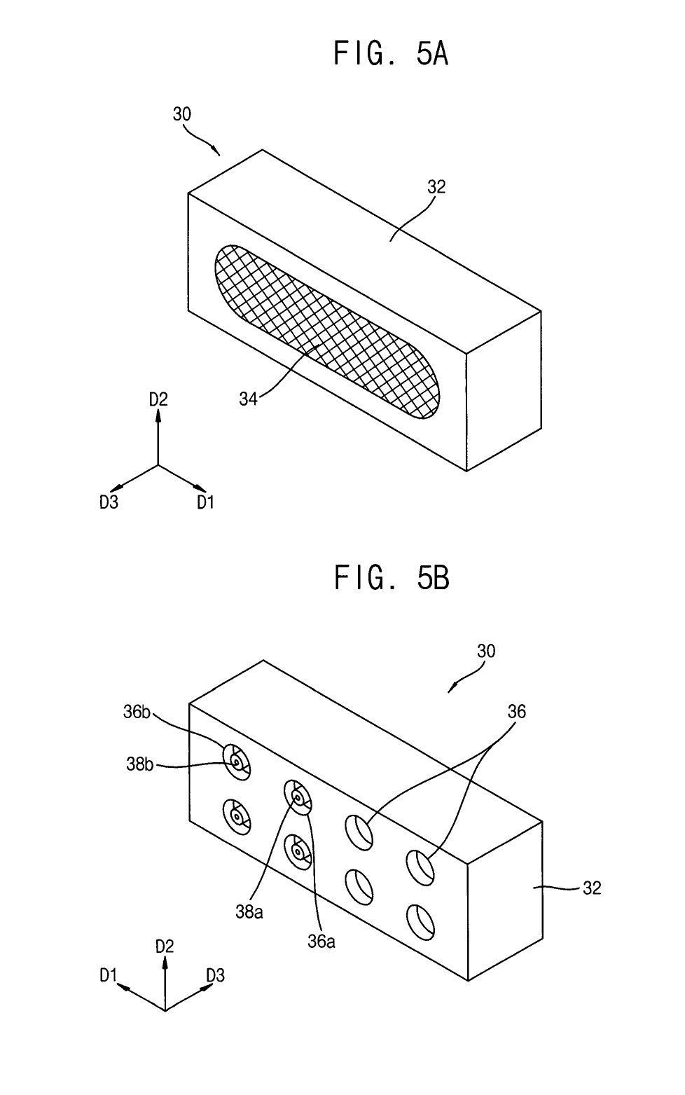

FIGS. 5A and 5B are perspective views illustrating another exemplary embodiment of a block of FIG. 1 in detail.

Referring to FIGS. 5A and 5B, a first functional block 30 includes a body portion 32, and a functional portion 34 disposed on the body portion 32.

A groove 36 is defined in a bottom surface of the body 32. A first groove 36a and a second groove 36b are further defined in the bottom surface of the body portion 32.

A first connecting terminal 38a is disposed in the first groove 36a. The first connecting terminal 38a is electrically connected to the functional portion 34. An electrical signal inputted through the first connecting terminal 38a drives the functional portion 34.

Referring to FIGS. 4, 5A and 5B, the first groove 36a of the first functional block 30 is configured to receive the first connecting protrusion 10a of the frame, so that the first terminal 18a of the first connecting protrusion 10a is electrically connected to the first connecting terminal 38a in the first groove 36a of the first functional block 30. In an exemplary embodiment, for example, a power signal may be applied to the functional portion 34 through the first terminal 18a and the first connecting terminal 38a.

A second connecting terminal 38b is disposed in the second groove 36b. The second connecting terminal 38b is electrically connected to the functional portion 34. An electrical signal inputted through the second connecting terminal 38b drives the functional portion 34.

Referring again to FIGS. 4, 5A and 5B, the second groove 36b of the first functional block 30 receives the second connecting protrusion 10b of the frame, so that the second terminal 18b of the second connecting protrusion 10b is electrically connected to the second connecting terminal 38b of the second groove 36b of the first functional block 30. In an exemplary embodiment, for example, first and second signals may be applied to the functional portion 34 through the second terminal 18b and the second connecting terminal 38b.

The first functional portion 34 may perform various functions using an electrical signal. In an exemplary embodiment, for example the first functional portion 34 may be configured to function as a speaker which generates sound using the electrical signal and the power signal through the first and second terminals 18a and 18b. That is, the functional block 30 may not only contribute to a custom bezel design of the display apparatus, but may also operate to provide a function to the bezel of the display apparatus.

FIG. 6 is an enlarged perspective view illustrating another exemplary embodiment of a portion of a bezel surface of a frame of a display apparatus according to the invention.

Referring to FIG. 6, a plurality of protrusions 10 is disposed on a first bezel surface 110 of a first frame portion 100. A first input/output connector CT1 is further disposed in and/or on the first bezel surface 110.

The protrusion 10 is substantially same as a protrusion of FIG. 4. Thus, any further detailed descriptions concerning the same elements will be omitted.

The first input/output connector CT1 is disposed in and/or on the first bezel surface 110. The first input/output connector CT1 may be disposed between adjacent protrusions 10. An electrical signal may be input to or output from the first input/output connector CT1.

The first input/output connector CT1 may be defined by a recess in the first frame portion 100, extended into the first frame portion 100 in a direction opposite to the third direction D3 which is a protruding direction of the protrusion 10 with respect to the first bezel surface 110. Thus, block 20 of FIGS. 2A and 2B may be combined with a portion at which the first input/output connector CT1 is disposed.

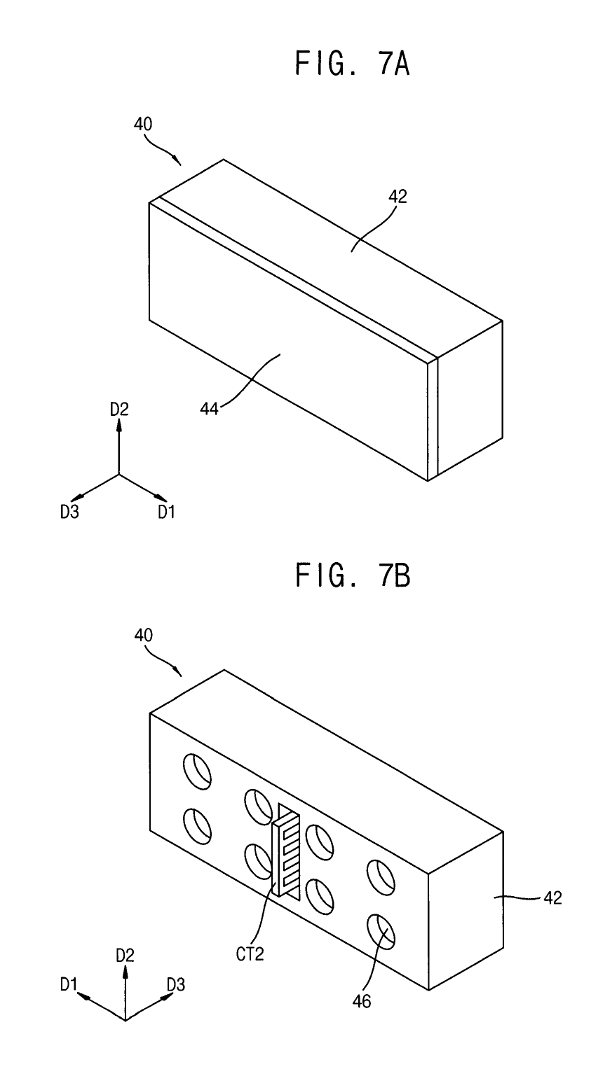

FIGS. 7A and 7B are perspective views illustrating still another exemplary embodiment of a block of a display apparatus according to the invention.

Referring to FIGS. 7A and B, a second functional block 40 includes a body portion 42, and an identification portion 44 disposed on the body portion 42. Text, characters and/or numbers such as relating to a function of the second functional block 40 may be disposed such as by writing or other means on the identification portion 44, such that the identification portion functions as a name tag 44. In an exemplary embodiment, for example, when the second functional block 40 is a universal serial bus (“USB”) storage medium, text of “USB” may be disposed on the name tag 44.

A groove 46 is defined in a bottom surface of the body portion 42. A second input/output connector CT2 is further disposed in and/or on the bottom surface of the body portion 42.

Referring again to FIG. 6, the second input/output connector CT2 of the second functional block 40 may be configured to be electrically connected to the first input/output connector CT1 of the first frame portion 100. The groove 46 defined in the bottom surface of the second functional block 40 is configured to receive the protrusion 10 of the first bezel surface 110 to combine the second functional block 40 with the first bezel surface 110 and the frame. In an exemplary embodiment, the second input/output connector CT2 is inserted in the first input/output connector CT1, so that the first input/output connector CT1 and the second input/output connector CT2 may be electrically connected to each other.

Accordingly, an electrical signal may be input to and output from the second functional block 40 via the second input/output connector CT2 and the first input/output connector CT1. In an exemplary embodiment, for example, when the second functional block 40 is a USB storage medium, data may be sent to and received from a processer of the display apparatus (not shown) through the first and second input/output connectors CT1 and CT2, so that a desired image is displayed on a display portion (refer to DP of FIG. 1) and/or that an image displayed on the display portion may be stored by the USB storage medium second functional block 40.

Although various shapes and functions of the blocks to be combined with the frame are illustrated in the exemplary embodiments, the block is not to be construed as limited to the exemplary embodiments. In an exemplary embodiment, for example, the block may be a functional block which is combined with the frame and connects the display apparatus to a sub-display such as a tablet personal computer (“PC”), a mobile phone, etc. Electrical signals may be sent from and received by the functional block and the sub-display, respectively.

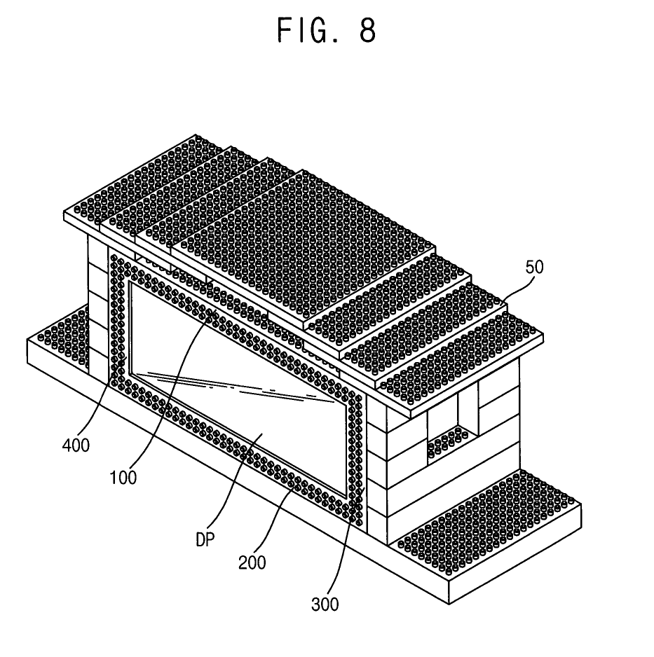

FIG. 8 is a perspective view of an exemplary embodiment of a surrounding assembly for a display apparatus according to the invention.

Referring to FIG. 8, a block assembly 50 is disposed on a display apparatus to define a custom frame and bezel structure of the display apparatus. The display apparatus includes a display portion DP and a frame. The frame includes a first frame portion 100, a second frame portion 200, a third frame portion 300 and a fourth frame portion 400. The display apparatus is substantially same as the display apparatus of FIG. 1 or 3A and 3B. Thus, any further detailed description concerning the same element will be omitted.

The block assembly 50 includes a plurality of blocks having various shapes. The blocks may be combined with each other using protrusions and grooves defined in the blocks. In an exemplary embodiment, for example, a block assembly having a house shape may be assembled using one or more exemplary embodiment of a block according to the invention, and a display portion DP may correspond to a window defined by the house shape.

A plurality of protrusions (refer to 10 of FIG. 1) are disposed on the first to fourth frame portions 100, 200, 300 and 400. In addition, a plurality of grooves (refer to 56 of FIG. 3B) may be defined in the first to fourth frame portions 100, 200, 300 and 400. Thus, the display apparatus and the block assembly 50 may be combined with each other using the protrusions and the grooves of one or more exemplary embodiment of a block according to the invention.

According to one or more exemplary embodiment of the invention, a plurality of protrusions is disposed on a frame of a display apparatus. The protrusions have same shapes each other, and are arranged spaced apart from each other by a uniform gap, so that a block may be combined with any portion of the frame. Thus, a user may design a bezel of the display apparatus.

In addition, one or more exemplary embodiment of the blocks of the invention may include various materials, so that the user may further design a bezel of the display apparatus.

In addition, one or more exemplary embodiment of the block may include a functional block configured to be combined with on the frame and provide various functions such as storage, audio or visual functions.

The foregoing is illustrative of the invention and is not to be construed as limiting thereof. Although a few exemplary embodiments of the invention have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific exemplary embodiments disclosed, and that modifications to the disclosed exemplary embodiments, as well as other exemplary embodiments, are intended to be included within the scope of the appended claims. The invention is defined by the following claims, with equivalents of the claims to be included therein.

What is claimed is:

1. A display apparatus comprising:
a display portion configured to display an image;
a frame surrounding the display portion, and comprising a plurality of protrusions having same shapes and arranged spaced apart by a uniform gap; and
a block in which a groove is defined and configured to receive a protrusion of the frame, configured to be combined with the frame.

2. The display apparatus of claim 1, wherein
the frame further comprises:
a first frame portion which extends in a first direction;
a second frame portion which extends in the first direction and is spaced apart from the first frame portion in a second direction which is substantially perpendicular to the first direction;
a third frame portion which extends in the second direction and connects the first frame portion and the second frame portion to each other; and
a fourth frame portion which extends in the second direction and connects the first frame portion and the second frame portion to each other,
the first frame portion comprises a first bezel surface and a first side surface, wherein the first bezel surface is in a plane parallel with a plane defined by the first and second directions, and the first side surface is connected with the first bezel surface and extends in a third direction which is substantially perpendicular to the first and second directions,
the second frame portion comprises a second bezel surface and a second side surface, wherein the second bezel surface is in the plane parallel with the plane defined by the first and second directions, and the second side surface is connected with the second bezel surface and extends in the third direction,
the third frame portion comprises a third bezel surface and a third side surface, wherein the third bezel surface is in the plane parallel with the plane defined by the first and second directions, and the third side surface is connected with the third bezel surface and extends in the third direction,
the fourth frame portion comprises a fourth bezel surface and a fourth side surface, wherein the fourth bezel surface is in the plane parallel with the plane defined by the first and second directions, and the fourth side surface is connected with the fourth bezel surface and extends in the fourth direction, and
the protrusions extend from the first to fourth bezel surfaces.

3. The display apparatus of claim 2, wherein the protrusions are further extended from the first side surface of the first frame portion.

4. The display apparatus of claim 2, wherein
a plurality of grooves are defined in the second side surface of the second frame portion, and
each groove of the second side surface has a same shape as the groove defined in the block.

5. The display apparatus of claim 2, wherein each of a protrusion among the plurality of protrusions of the frame comprises:
an extending portion extended from the first, second, third or fourth bezel surface, and
a head portion extended from the extending portion.

6. The display apparatus of claim 5, wherein the extending portion has a cylindrical shape, and the head portion has a truncated circular cone shape.

7. The display apparatus of claim 5, wherein the protrusion further comprises:
a recess defined in the head portion, and
a terminal disposed in the recess and configured to receive an electrical signal thereto and/or output the electrical signal therefrom.

8. The display apparatus of claim 7, wherein
the block is a functional block comprising a connecting terminal disposed in the groove thereof and configured to be electrically connected to the terminal of the protrusion, and
the protrusion of the frame received in the groove of the functional block electrically connects the connecting terminal of the functional block and the terminal of the protrusion.

9. The display apparatus of claim 8, wherein the functional block is configured to receives the electrical signal and output sound.

10. The display apparatus of claim 8, wherein the functional block is a storage medium which is configured to receive the electrical signal thereto and output the electrical signal therefrom.

11. The display apparatus of claim 2, wherein the first frame portion further comprises a first input/output connector which is configured to receive an electrical signal thereto output the electrical signal therefrom.

12. The display apparatus of claim 11, wherein
the block is a functional block comprising a second input/output connector configured to be electrically connected to the first input/output connector of the first frame portion.

13. The display apparatus of claim 1, wherein
the block comprises a body portion, and a decorative portion on the body portion, and
the decorative portion comprises a different material from that of the body portion.

14. The display apparatus of claim 13, wherein the decorative portion comprises lacquer, wood or metal.

15. The display apparatus of claim 1, wherein a plurality of grooves is defined in a bottom surface of the block.

16. The display apparatus of claim 15, wherein
a plurality of protrusions is extended from a top surface of the block opposite to the bottom surface, and
the plurality of protrusion of the block has a shape substantially the same as that of the plurality of protrusions of the frame.

17. A display apparatus comprising:
a display portion configured to display an image; and
a frame surrounding the display portion, comprising a plurality of protrusions protruded therefrom, having same shapes as each other and arranged spaced apart from each other by a uniform gap, and to which are respectively combined grooves of a block which is configured to be combined with the frame.

18. The display apparatus of claim 17, wherein a protrusion among the plurality of protrusions comprises a terminal configured to be electrically connected to a block connecting terminal disposed in a groove among the grooves of the block.

19. The display apparatus of claim 17, wherein the frame further comprises a first input/output connector disposed between adjacent protrusions and configured to be electrically connected to a second input/output connector of the block.
